(19) United States
(12) Patent Application Publication
(10) Pub. No.: US 2010/0009273 A1
(43) Pub. Date: Jan. 14, 2010

(54) MASK AND METHOD FOR MANUFACTURING THE SAME

(76) Inventor: Jong-Doo Kim, Eumseong-gun (KR)

Correspondence Address: SHERR & VAUGHN, PLLC, 620 HERNDON PARKWAY, SUITE 320, HERNDON, VA, 20170, US

(21) Appl. No.: 12/502,768

(22) Filed: Jul. 14, 2009

(30) Foreign Application Priority Data
Jul. 14, 2008 (KR) 10-2008-0068000

(51) Int. Cl. G03F 1/00

(52) U.S. Cl. 430/5

(57) ABSTRACT

A mask for use in an exposure process and a method for manufacturing the same are provided, the mask including a main pattern formed over a reticle substrate; a plurality of dummy patterns formed over the reticle substrate and spaced apart from the main pattern by a predetermined distance; and a light shielding layer formed over at least one of the plurality of dummy patterns. A dummy patterns may include a fine dummy pattern having a resolution equal to or less than a limit resolution so as not to form a pattern image on a wafer during an exposure process.

The present application claim priority under 35 U.S.C. §119 to Korean Patent Application No. 10-2008-0068000, filed on Jul. 14, 2008, which is hereby incorporated by reference in its entirety.

### BACKGROUND

A reticle for use in an exposure process of semiconductor manufacturing processes may be a transparent plate having patterned images to be transmitted to a photoresist-coated wafer. Perfectly manufacturing the reticle is critical. Circuits of the wafer are ultimately patterned from the reticle. In an effort to define a progressively decreasing critical dimension (CD) of semiconductor devices on and/or over a wafer, an exposure process is carried out using a light source with a shorter wavelength (e.g., ArF 193 nm). In addition, a phase shifting mask has been developed and used in the exposure process.

In the manufacture of semiconductor wafers, forming a photoresist pattern using photolithography techniques may problematically cause flare noise. When a mask pattern (e.g., a reticle) is formed and is exposed to provide a wafer with a pattern corresponding to the mask pattern, the flare noise causes variation in the CD of the pattern provided on and/or over the wafer. It is known that the flare noise occurs because light beams having passed through the mask pattern lose their paths and the intensity of exposure light in a low density pattern region increases.

FIG. 1A illustrates a first aerial image f1 having no flare noise, and FIG. 1B illustrates a second aerial image f2 affected by flare noise. In the second aerial image f2, the background intensity of light approaches a reference line Rf under the influence of flare noise. Thus, when comparing the first aerial image f1 and the second aerial image f2 with each other, the images f1 and f2 may cause a difference in CDs to be realized on a wafer.

Generally, a semiconductor mask, e.g., a phase shifting mask, includes a main pattern and a dummy pattern formed thereon and/or thereover. The main pattern may be a gate pattern, metal line pattern, trench pattern, or contact-hole pattern. The dummy pattern may be formed to prevent the occurrence of dishing in a chemical mechanical polishing (CMP) process, or to reduce loading effects in an etching process. A dummy pattern image corresponding to the dummy pattern may be patterned on and/or over a wafer.

FIG. 2A illustrates a phase shifting mask including general dummy patterns to reduce flare noise, and FIG. 2B illustrates the mask taken along the line I-I′ of FIG. 2A. Reticle 200 includes main pattern A and first dummy pattern B and second dummy pattern C formed on and/or over quartz substrate 210. Although first dummy pattern B and second dummy pattern C may be formed between main patterns, first dummy pattern B and second dummy pattern C are spaced apart from main pattern A by predetermined distance H, in order to have no effect on a main pattern image to be formed on and/or over a wafer. First dummy pattern B and second dummy pattern C reduce the quantity of exposure light, thus reducing flare noise to some extent.

### SUMMARY

Embodiments relate to a mask and a method for manufacturing the same that effectively reduces flare noise during a photolithography process using a fine dummy pattern.

In accordance with embodiments, a mask may include at least one of the following: a main pattern formed on and/or over a reticle substrate; a plurality of dummy patterns arranged on and/or over the reticle substrate and spaced apart from the main pattern by a predetermined distance; and a light shielding layer formed on and/or over at least one of the plurality of dummy patterns.

In accordance with embodiments, a mask may include at least one of the following: a main pattern formed over a reticle substrate; a first plurality of dummy patterns formed over the reticle substrate and aligned adjacent a first side of the main pattern in a direction substantially parallel to and spaced apart from the main pattern; a second plurality of dummy patterns formed over the reticle substrate and aligned adjacent a second side of the main pattern in a direction substantially parallel to and spaced apart from the main pattern; and a third plurality of dummy patterns formed over the reticle substrate and aligned in the space between the main pattern and the first plurality of dummy patterns and the space between the main pattern and the second plurality of dummy patterns, the third plurality of dummy patterns having a resolution that is one of equal to and less than a limit resolution.

In accordance with embodiments, a mask may include at least one of the following: a main pattern formed on and/or over a reticle substrate; dummy patterns arranged on and/or over the reticle substrate and spaced apart from the main pattern; and at least one fine dummy pattern formed on and/or over the reticle substrate between the main pattern and the dummy patterns, the at least one fine dummy pattern having a resolution equal to or less than a limit resolution so as not to form a pattern image on and/or over a wafer during an exposure process.

In accordance with embodiments, a method for manufacturing a mask may include at least one of the following: forming a main pattern on and/or over a reticle substrate; and then forming a plurality of dummy patterns on and/or over the reticle substrate and spaced apart from the main pattern; and then forming a light shielding layer on and/or over at least one of the plurality of dummy patterns.

In accordance with embodiments, a method for manufacturing a mask may include at least one of the following: preparing a reticle substrate; and then forming a main pattern, a dummy pattern spaced apart from the main pattern by a predetermined distance and at least one fine dummy pattern arranged between the main pattern and the dummy pattern on and/or over the reticle substrate, the at least one fine dummy pattern having a resolution equal to or less than a limit resolution so as not to form a pattern image on and/or over a wafer during an exposure process.

### DRAWINGS

FIGS. 1A and 1B illustrate aerials image having no flare noise and affected by flare noise.

FIGS. 2A and 2B illustrates a phase shifting mask including general dummy patterns to reduce flare noise.

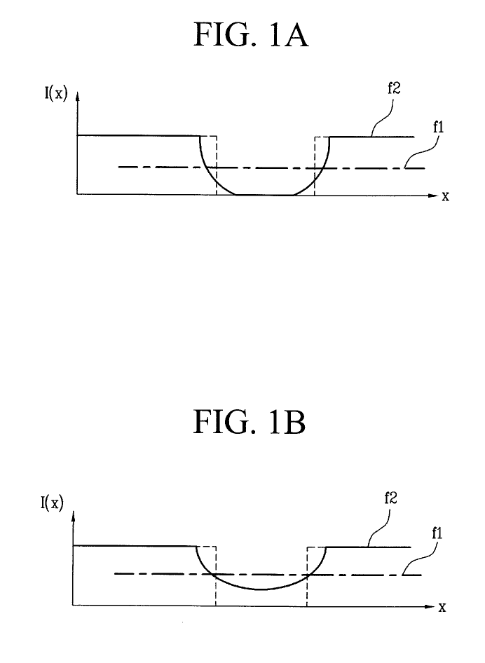

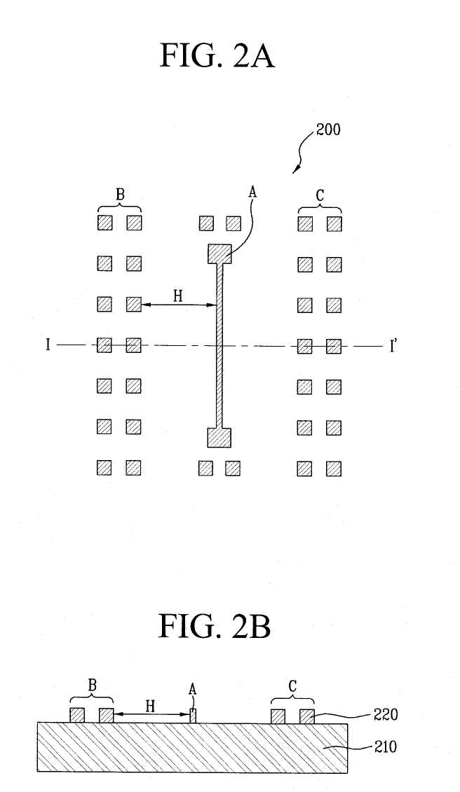

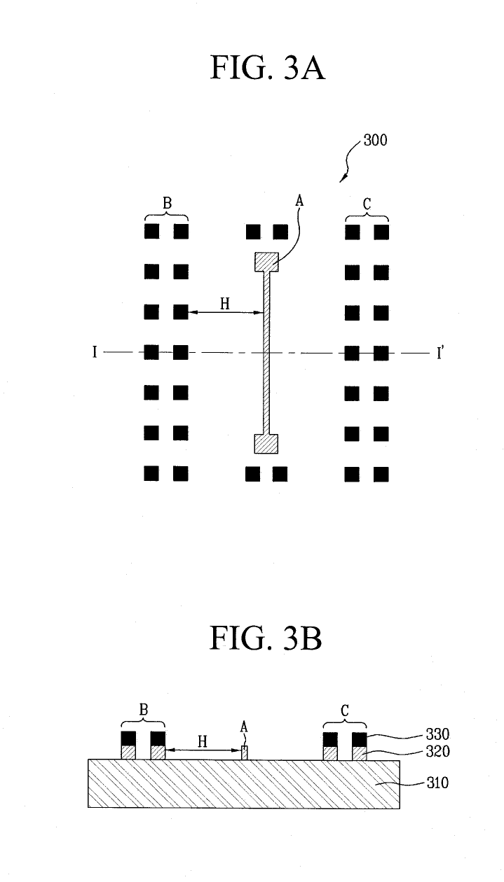

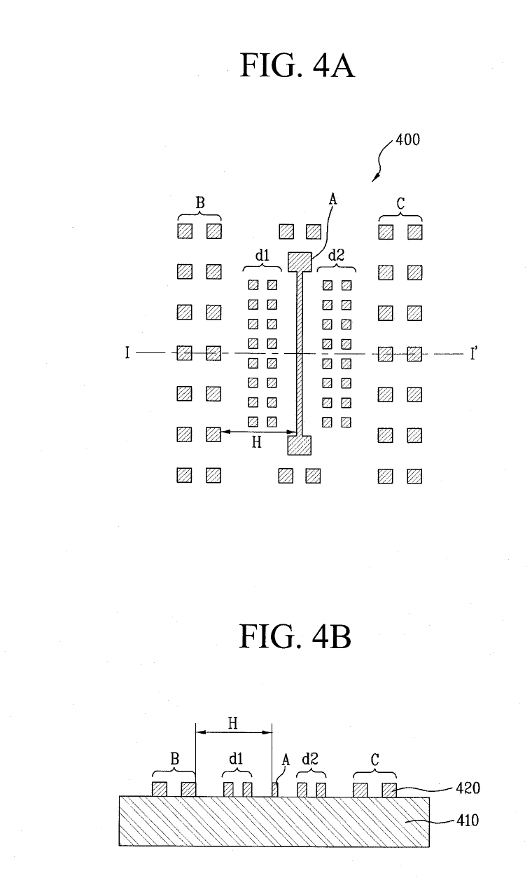

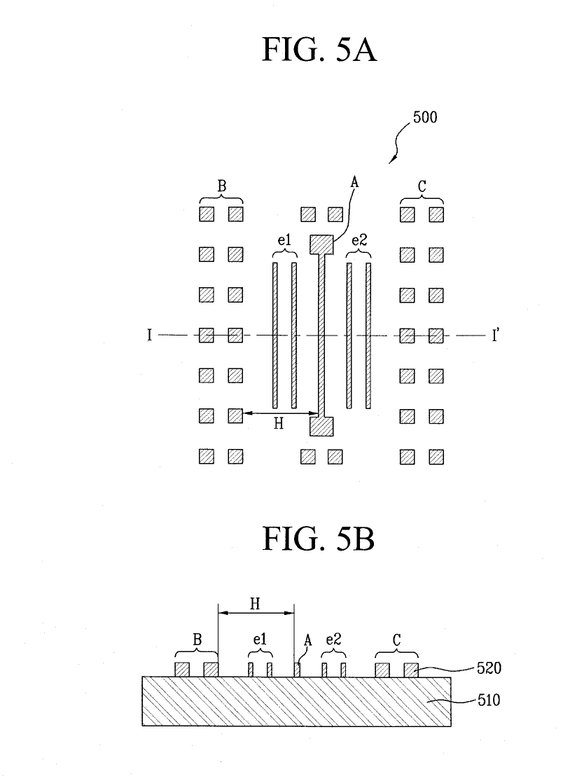

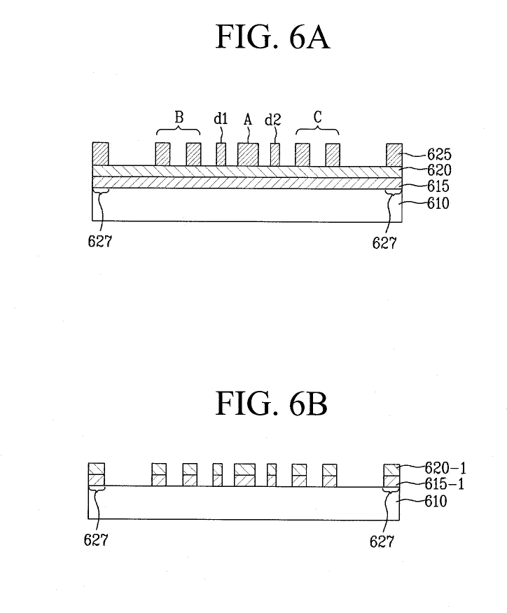

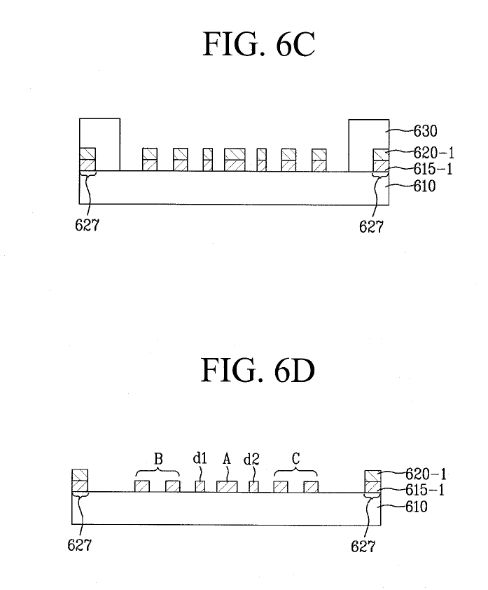

Example FIGS. 3 and 6 illustrates a mask and a method of manufacturing a mask in accordance with embodiments.

### DESCRIPTION

Example FIG. 3A illustrates mask 300 in accordance with embodiments while example FIG. 3B illustrates the mask taken along the line I-I′ of example FIG. 3A.

As illustrated in example FIGS. 3A and 3B, mask 300 includes reticle substrate 310, main pattern A, and dummy patterns 320 including first dummy pattern B and second dummy pattern C, and light shielding layer 330 formed on and/or over first dummy pattern B and second dummy pattern C. Reticle substrate 310 may be composed of quartz, for instance, such quartz may be composed primarily of fusible silica or silicon dioxide (SiO₂).

Main pattern A is formed on and/or over reticle substrate 310, and may be formed to directly contact reticle substrate 310. Main pattern A may be a gate pattern, a metal line pattern, a devise isolation layer pattern, a via-hole pattern, and the like, which will be formed on and/or over a wafer.

Dummy patterns 320 including first dummy pattern B and second dummy pattern C are formed on and/or over reticle substrate 310 and spaced apart from main pattern A by predetermined distance H. Dummy patterns 320 may be formed to directly contact reticle substrate 310. Main pattern A and dummy patterns 320 may be composed of a metal compound having a predetermined light transmittance, for example in a range between 5 to 10%. Such metal compound may be one of molybdenum silicide (MoSi), chromium oxide (Cr₂O₃), and chromium nitride (CrN).

Although example FIGS. 3Aa and 3B illustrate a single main pattern A, a plurality of main patterns may be formed on and/or over reticle substrate 310 and dummy patterns 320 may be formed between the main patterns and spaced apart by predetermined distance H in order to have no effect on a main pattern image to be formed on and/or over a wafer. Predetermined distance H between main pattern A and first dummy pattern B and second dummy pattern C may be determined based upon vendor requirements, or may be standardized on a per manufacturer basis.

Light shielding layer 330 may be formed on and/or over at least one of the dummy patterns 320. Light shielding layer 330 may be formed to directly contact dummy patterns 320. For example, light shielding layer 330 may be formed on and/or over the respective dummy patterns 320. Light shielding layer 330 may be composed of a metal having a light transmittance of 0%, such as chromium (Cr). Chromium completely shields light, thus minimizing the effect of light, i.e., reducing flare noise.

Mask 300 illustrated in example FIG. 3A may be a phase shifting mask and may be fabricated as follows. First, a metal layer 320, which may be composed of one of molybdenum silicide (MoSi), chromium oxide (Cr₂O₃), and chromium nitride (CrN), is formed on and/or over quartz reticle substrate 310. A second metal layer 330, which may be composed of chromium is then formed on and/or over first metal layer 320. A first photoresist layer is then formed on and/or over second metal layer 330 and then patterned to form main pattern A, first dummy pattern B and second dummy pattern C. Such formation may occur simultaneously through the patterning of the first photoresist layer. The first metal layer 320 and second metal layer 330 are then etched away using the first photoresist pattern as an etching mask. Next, the first photoresist pattern is removed via ashing or stripping processes.

A second photoresist layer is then formed on and/or over reticle substrate 310 including main pattern A, first dummy pattern B, second dummy pattern C and second metal layer 330. The second photoresist layer is then patterned to expose a portion of second metal layer 330 on and/or over main pattern A and another portion of second metal layer 330 formed on and/or over at least one of first dummy pattern B and second dummy pattern C. The second photoresist pattern may expose the portion of second metal layer formed on and/or over the entirety of or a portion of the dummy patterns. Second metal layer 330 formed on and/or over main pattern A and at least one of the dummy patterns is etched away using the second photoresist pattern as an etching mask, thus forming light shielding layer 330. Thereafter, the second photoresist pattern is removed.

Example FIG. 4A illustrates mask 400 in accordance with embodiments while example FIG. 4B illustrates mask 400 taken along the line I-I′ of example FIG. 4A.

As illustrated in example FIGS. 4A and 4B, mask 400 includes reticle substrate 410, main pattern A, a dummy pattern 420 including first dummy pattern B, second dummy pattern C, and at least one fine dummy pattern d1, d2. Fine dummy pattern d1, d2 may be formed at an overall size that is less than the overall size of first dummy pattern B and second dummy pattern C. Main pattern A is formed on and/or over reticle substrate 410 and may directly contact reticle substrate 410. As described above, main pattern A may be a gate pattern, a metal line pattern, a device isolation layer pattern, a via-hole pattern, and the like, which will be formed on and/or over a wafer.

First dummy pattern B and second dummy pattern C are formed on and/or over (and may directly contact) reticle substrate 410 and spaced apart from main pattern A by predetermined distance H in order to have no effect on a main pattern image to be formed on and/or over a wafer as described above. First dummy pattern B and second dummy pattern C are formed to prevent the occurrence of dishing in a CMP process, or to reduce loading effects in an etching process. Dummy pattern images corresponding to first dummy pattern B and second dummy pattern C are formed on and/or over a wafer.

Fine dummy pattern d1, d2 may be formed on and/or over (and may directly contact) reticle substrate 410 in the spaces between main pattern A and first dummy pattern B and main pattern A and second dummy pattern C. Fine dummy pattern d1, d2 may have a resolution equal to or less than a limit resolution so as not to form a pattern image on and/or over a wafer during an exposure process. The limit resolution may be determined by wavelength λ and numerical aperture NA of an illumination system. Specifically, the limit resolution may be determined by Rayleigh's Equation as represented by the following Equation 1.

R=(k×λ)/(NA) Equation 1

where R represents resolution, K represents a constant, λ represents a wavelength of an illumination system, and NA represents a numerical aperture of the illumination system.

Once the limit resolution is calculated by substituting R, k and λ under certain given exposure conditions into the above Equation 1, a critical dimension (CD) of the fine dummy pattern d1, d2 may be determined such that a resolution of fine dummy pattern d1, d2 is equal to or less than the calculated limit resolution. Thus, although mask 400 includes fine dummy pattern d1 or d2, no fine dummy pattern image is formed on and/or over a wafer after completion of an exposure process. Fine dummy pattern d1, d2 may have a square, rectangular or circular cross-section. For example, two or more rows of fine dummy patterns d1, d2 may be arranged on and/or over reticle substrate 410 in the space between main pattern A and first dummy pattern B and main pattern A and second dummy pattern C so as to be spaced apart from each other by a predetermined distance.

Example FIG. 5A illustrates mask 500 in accordance with embodiments while example FIG. 5B illustrates mask 500 taken along the line I-I′ of example FIG. 5A.

As illustrated in example FIGS. 5A and 5B, mask 500 includes main pattern A formed on and/or over (and may directly contact) reticle substrate 510, and dummy pattern 520 including first dummy pattern B, second dummy pattern C formed on and/or over (and may directly contact) reticle substrate 510 and spaced apart from main pattern A by predetermined distance H, and at least one fine dummy pattern e1, e2 formed on and/or over (and may directly contact) reticle substrate 510 in the space between main pattern A and first dummy pattern B and main pattern A and second dummy pattern C. Fine dummy pattern e1, e2 have a linear cross-section with a resolution equal to or less than a limit resolution so as not to form a pattern image on and/or over a wafer during an exposure process. Mask 500 illustrated in example FIGS. 5A and 5B is the same as mask 400 illustrated in example FIGS. 4A and 4B except for the fact that fine dummy pattern e1, e2 has a linear cross-section.

Example FIGS. 6A to 6D illustrate a method of forming masks 400, 500 of example FIGS. 4 and 5. As illustrated in example FIG. 6A, a first metal layer 615, which may be composed of a metal compound such as one of molybdenum silicide (MoSi), chromium oxide (Cr₂O₃), and chromium nitride (CrN), is formed on and/or over (and may directly contact) reticle substrate 610. Second metal layer 620 composed of a metal such as chromium (Cr) layer 620 is then formed on and/or over (and may directly contact) first metal layer 615. First photoresist pattern 625 is formed on and/or over (and may directly contact) second metal layer 620. The first photoresist pattern 625 may then be patterned to form main pattern A, first dummy pattern B, second dummy pattern C, and fine dummy patterns d1, d2. First photoresist pattern 625 may be patterned so as not to expose outermost lateral edge regions 627 of reticle substrate 610.

As illustrated in example FIG. 6B, first metal layer 615 and second metal layer 620 are then etched using third photoresist pattern 625 as an etching mask, thereby forming pattern 615-1 including main pattern A and dummy patterns B, C, d1 and d2. First photoresist pattern 625 may be changed based on the desired geometric cross-section of fine dummy patterns d1, d2 or e1, e2 of masks 400, 500 illustrated in example FIGS. 4 and 5. Accordingly, second metal layer 620-1 remains on and/or over (and may directly contact) pattern 615-1 including main pattern A and dummy patterns B, C, d1 and d2 and also outermost edge regions 627 of reticle substrate 610. First photoresist pattern 625 is then removed via ashing or stripping processes.

As illustrated in example FIG. 6C, second photoresist pattern 630 is then formed on and/or over (and may directly contact) reticle substrate 610 including pattern 615-1. Second photoresist pattern 630 is then patterned to expose main pattern A, dummy patterns B and C, and fine dummy patterns d1, d2 including second metal layer 620-1 remains. Second photoresist pattern 630 is patterned so as not to expose a portion of second metal layer 620-1 on and/or over outermost edge region 627 of reticle substrate 610.

As illustrated in example FIG. 6D, after etching away a portion of second metal layer 620-1 formed on and/or over main pattern A, dummy patterns B and C and fine dummy patterns d1, d2 using second photoresist pattern 630 as an etching mask, second photoresist pattern 630 is removed.

To prevent light passing outermost edge region 627 from having an effect on a main pattern image to be formed on and/or over a wafer, second metal layer 620-1 formed on and/or over outermost edge region 627 of reticle substrate 610 may remain to prevent the exposure of outermost edge region 627.

During exposure and developing processes using masks 300, 400 and 500 in accordance with embodiments, the fine dummy patterns formed between the main pattern and the dummy patterns may reduce flare noise, thereby assuring a desired photolithography process margin and improving uniformity of a critical dimension to be patterned on a wafer.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A mask comprising:
a main pattern formed over a reticle substrate;
a plurality of dummy patterns formed over the reticle substrate and spaced apart from the main pattern by a predetermined distance; and
a light shielding layer formed over at least one of the plurality of dummy patterns.

2. The mask of claim 1, wherein the main pattern, the dummy patterns and the light shielding layer are each composed of a metal material.

3. The mask of claim 2, wherein the main pattern and the dummy pattern are composed of the same material.

4. The mask of claim 3, wherein the main pattern and the dummy pattern are composed of one of molybdenum silicide (MoSi), chromium oxide (Cr₂O₃), and chromium nitride (CrN).

5. The mask of claim 4, wherein the light shielding layer is composed of chromium (Cr).

6. The mask of claim 3, wherein the main pattern and the dummy pattern are composed of molybdenum silicide (MoSi).

7. The mask of claim 6, wherein the light shielding layer is composed of chromium (Cr).

8. The mask of claim 1, wherein the main pattern and the dummy pattern are composed of one of molybdenum silicide (MoSi), chromium oxide (Cr₂O₃), and chromium nitride (CrN) and the light shielding layer is composed of chromium (Cr).

9. A mask comprising:
a main pattern formed over a reticle substrate;
a first plurality of dummy patterns formed over the reticle substrate and aligned adjacent a first side of the main pattern in a direction substantially parallel to and spaced apart from the main pattern; and
a second plurality of dummy patterns formed over the reticle substrate and aligned adjacent a second side of the main pattern in a direction substantially parallel to and spaced apart from the main pattern;
a third plurality of dummy patterns formed over the reticle substrate and aligned in the space between the main pattern and the first plurality of dummy patterns and the space between the main pattern and the second plurality of dummy patterns,
wherein the third plurality of dummy patterns have a resolution that is one of equal to and less than a limit resolution.

10. The mask of claim 9, wherein the overall size of the third plurality of dummy patterns is less than the overall size of the first and second plurality of dummy patterns.

11. The mask of claim 9, wherein the third plurality of dummy patterns have a rectangular cross-section.

12. The mask of claim 3, wherein the third plurality of dummy patterns have a linear cross-section.

13. The mask of claim 9, wherein the third plurality of dummy patterns are arranged as a first pair of rows extending in parallel to each other in the space between the main pattern and the first plurality of dummy patterns and a second pair of rows extending in parallel to each other in the space between the main pattern and the second plurality of dummy patterns.

14. A method for manufacturing a mask comprising:
forming a main pattern over a reticle substrate and a plurality of dummy patterns over the reticle substrate and spaced apart from the main pattern; and then
forming a light shielding layer over at least one of the plurality of dummy patterns.

15. The method of claim 14, wherein forming the main pattern and the plurality of dummy patterns comprises:
sequentially forming a first metal layer over the reticle substrate and a second metal layer over the first metal layer; and then
forming a first photoresist pattern over the second metal layer; and then
performing an etching process on the first metal layer and the second metal layer using the first photoresist pattern as an etching mask.

16. The method of claim 15, wherein forming the light shielding layer comprises:
removing the first photoresist pattern after performing the etching process pattern; and then
forming a second photoresist pattern over the reticle substrate exposing the second metal layer over the main pattern and the plurality of dummy patterns; and then
performing a second etching process on the second metal layer using the second photoresist pattern as an etching mask.

17. The method of claim 16, wherein the light shielding layer is composed of chromium (Cr).

18. The method of claim 17, wherein the main pattern and the dummy pattern are composed of one of molybdenum silicide (MoSi), chromium oxide (Cr₂0₃), and chromium nitride (CrN) and the light shielding layer is composed of chromium (Cr).

19. The method of claim 14, wherein the light shielding layer is composed of chromium (Cr).

20. The method of claim 19, wherein the main pattern and the dummy pattern are composed of one of molybdenum silicide (MoSi), chromium oxide (Cr₂O₃), and chromium nitride (CrN) and the light shielding layer is composed of chromium (Cr).
